(19) United States
(12) Patent Application Publication
(10) Pub. No.: US 2005/0260840 A1
(43) Pub. Date: Nov. 24, 2005

(54) Method of fabricating T-shaped polysilicon gate by using dual damascene process

(76) Inventors: Shuang-Feng Yeh, Zhangjiang Hi-Tech Park (CN); Pin-Jen Chen, Zhangjiang Hi-Tech Park (CN); Hui-Ping Ma, Zhangjiang Hi-Tech Park (CN); Ta-Yung Pao, Zhangjiang Hi-Tech Park (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/098,495

(22) Filed: Apr. 5, 2005

(30) Foreign Application Priority Data
May 19, 2004 (CN) 200410018450X

(51) Int. Cl. H01L 21/336

(52) U.S. Cl. 438/585; 438/595; 438/684

(57) ABSTRACT

A method of fabricating a T-shaped polysilicon gate by using dual damascene process. An oxide layer, a hard mask layer, and a patterned first photoresist layer in sequence are formed on a semiconductor substrate. Using the patterned first photoresist layer as a mask, an etching process is performed on the hard mask layer to form a first trench. The patterned first photoresist layer is removed. An organic layer is then deposited in the first trench. A patterned second photresist layer is formed on the semiconductor substrate. Using the patterned second photresist layer as a mask, an etching process is performed on the hard mask layer to define a second trench dimension. The patterned second photoresist layer and the organic layer are removed. An oxide layer and a polysilicon layer are deposited in the first trench and the second trench. The residual hark mask layer is removed to obtain a T-shaped profile polysilicon gate.

### BACKGROUND OF THE INVENTION

1. Field of the Invention

The present invention relates to a method of forming a T-shaped polysilicon gate, and more particularly, to a method of fabricating a T-shaped polysilicon gate by using dual damascene process.

2. Description of the Prior Art

Many semiconductor devices and circuits are based on metal oxide semiconductor field effect transistors (MOSFETs). MOSFET device use the gate as a control gate. That is, the voltage signal of the gate controls the output performance. As semiconductor technology shrinks into the deep submicron region, devices have become more highly-integrated and reduced in dimension. When the source/drain junction of the transistor becomes a shallow junction, the main concerns about structure parameters are (1) the junction depth of the extension area, (2) the lateral length of the extension area, (3) the lateral doping concentration profile of the extension area and so on. Therefore, after the dimension shrinks into the deep submicron level, the transistors require lower miller capacitance and a higher driving current compared with conventional transistors. Conventional technology uses an energy with 10¹⁵ to perform the source/drain extension dopant process in order to obtain a higher driving current and reduce the miller capacitance.

However, in order to further shrink device dimensions, while performing the source/drain extension dopant process, the dopant is easily embedded in the polysilicon gate edge, resulting in easy breakdown of the polysilicon gate edge.

In view of this, the present invention provides a method of fabricating a T-shaped polysilicon gate by using dual damascene process in order to overcome the above-mentioned disadvantages. Also, the present invention reduces and controls the gate line width to increase the integration of the device.

### SUMMARY OF THE INVENTION

The present invention provides a method of fabricating a T-shaped polysilicon gate by using dual damascene process, which effectively prevents low polysilicon gate edge breakdown voltage caused by the dopant embedded in the polysilicon gate edge while performing the source/drain extension dopant process.

The present invention also provides a method of fabricating a T-shaped polysilicon gate by using dual damascene process, which has a smaller gate line width, thereby increasing the integration of the device.

These objects are accomplished by providing a method of fabricating a T-shaped polysilicon gate by using dual damascene process, comprising: providing a semiconductor substrate having isolation areas formed therein; forming an oxide layer, a hard mask layer, and a patterned first photoresist layer in sequence on the semiconductor substrate; performing an etching process on the hard mask layer and the oxide layer by using the patterned first photoresist layer as a mask until the semiconductor substrate is exposed, thereby forming a first trench, removing the patterned first photoresist layer; depositing an organic layer in the first trench, performing an etch back process on the organic layer until the surface of the organic layer is lower than the hard mask layer; forming a patterned second photoresist layer on the semiconductor substrate to define a second trench dimension to be etched, wherein the etch window dimension of the patterned second photoresist layer is larger than the first trench, performing an etching process by using the patterned second photoresist layer as a mask to form a second trench, removing the patterned second photoresist layer and the organic layer; performing an oxidation process on the semiconductor substrate to form a gate oxide layer on the surface of the semiconductor substrate; depositing a polysilicon layer on the semiconductor substrate to fill the first trench and the second trench, performing a planarization process on the polysilicon layer; removing the residual hard mask layer, removing the exposed oxide layer by using the polysilicon layer as a mask to obtain a T-shaped profile polysilicon gate.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 7 are sectional diagrams illustrating a T-shaped polysilicon gate according to a preferred embodiment of the present invention.

### DETAILED DESCRIPTION OF THE PREFERRED EMBODIMENTS

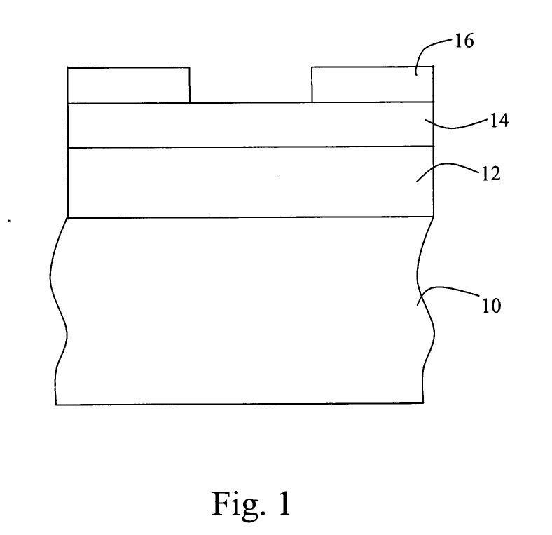

The present invention provides a method of fabricating a T-shaped polysilicon gate by using dual damascene process, as shown in FIGS. 1 through 7, which illustrate a T-shaped polysilicon gate according to a preferred embodiment of the present invention.

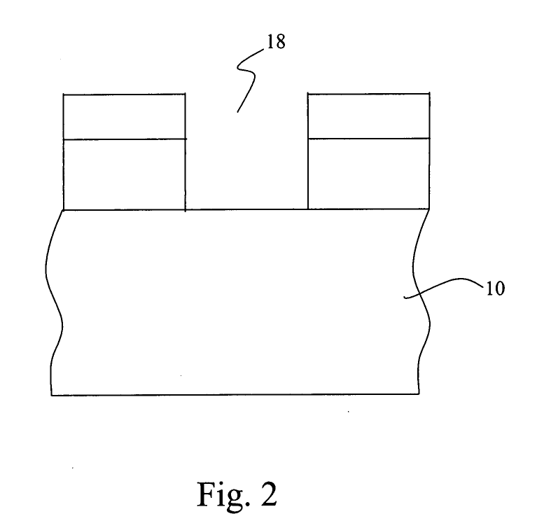

Refer to FIG. 1, a semiconductor substrate 10 having several isolation areas formed thereon is provided. An oxide layer 12, a hard mask layer 14, and a patterned first photoresist layer 16 in sequence are formed on the semiconductor substrate 10. The material of the hard mask layer 14 can be silicon oxynitride (SiOH) or tetraethyl-orthosilicate (TEOS) or other materials. The hard mask layer 14 is deposited by Low Pressure Chemical Vapor Deposition (LPCVD). Next, using the patterned first photoresist layer 16 as a mask, an etching process is performed on the hard mask layer 14 and the oxide layer 12 until the semiconductor substrate 10 is exposed, thereby forming a first trench 18. The patterned first photoresist layer 16 is removed to form the structure as shown in FIG. 2.

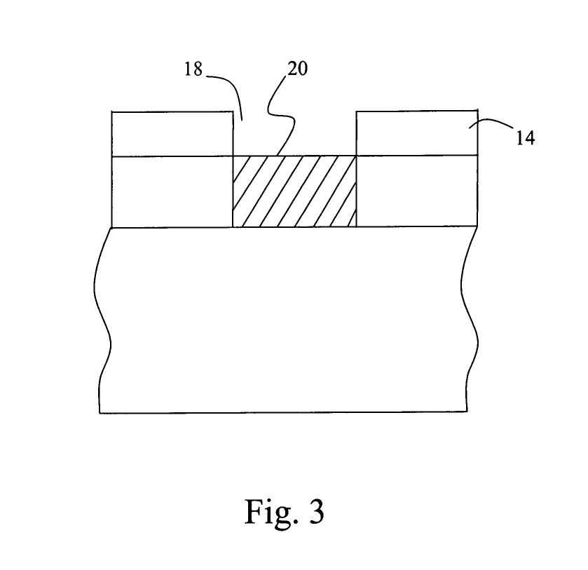

Referring to FIG. 3, an organic layer 20 is deposited in the first trench 18 by using a spin coating. The organic layer 20 can be a Bottom anti-reflective coating (BARC). An etching is then performed on the organic layer 20 until the surface of the organic layer 20 is lower than the hard mask layer 14.

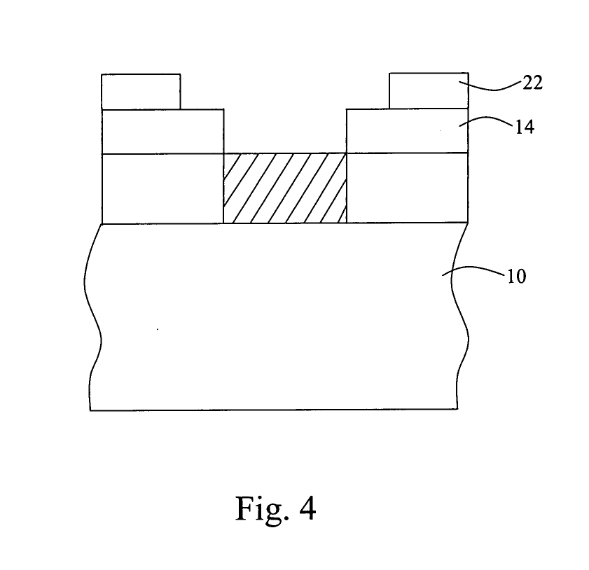

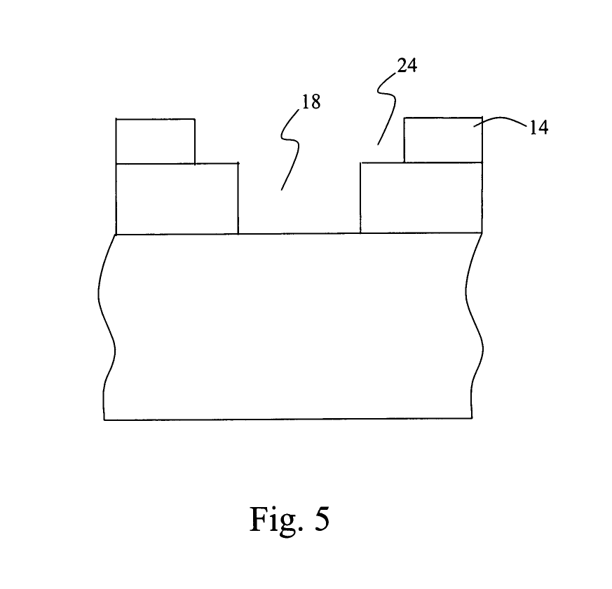

A patterned second photoresist layer 22 is then formed on the semiconductor substrate 10 to define the second trench dimension to be etched. An etch window dimension of the patterned second photoresist layer 22 is larger than the first trench, as shown in FIG. 4. Using the patterned second photoresist layer 22 as a mask, an etching process is continuously performed on the hard mask layer 14 to form a second trench 24. The patterned second photoresist layer 22 and the organic layer 20 are then removed to form the structure as shown in FIG. 5. As a result, the bottom of the first trench 18 maintains a nearly right angle due to the protection of the organic layer 22.

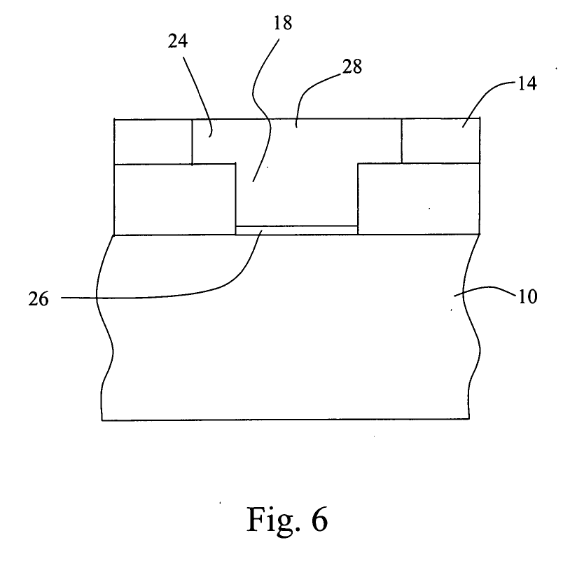

Next, an oxidation process is performed on the semiconductor 10. The oxidation process is performed by a Rapid thermal oxidation treatment. Since the Rapid thermal oxidation treatment does not react with the hard mask layer 14, oxygen plasma only reacts with the exposed semiconductor substrate 10 in the first trench 18 after performing the Rapid thermal oxidation process, thereby forming a gate oxide layer 26. A polysilicon layer 28 is deposited on the semiconductor substrate 10 to fill the first trench 18 and the second trench 24. A Chemical Mechanical Polishing (CMP) process is performed on the polysilicon layer 28 to remove the redundant polysilicon layer 28 in order to achieve a so-called Blanket planarization, resulting in forming the structure as shown in FIG. 6.

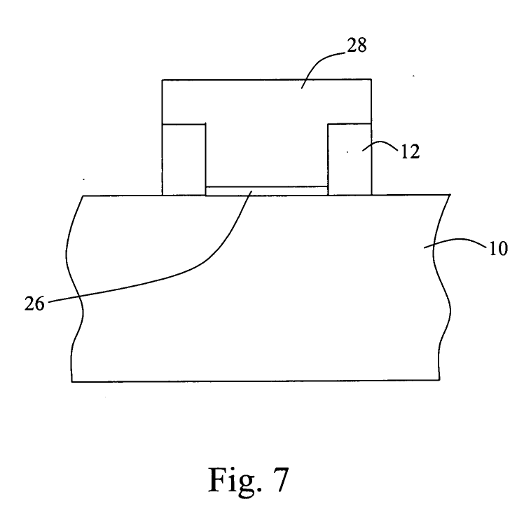

Finally, referring to FIG. 7, the residual hard mask layer 14 is removed. Using the polysilicon layer 28 as a mask, the oxide layer 12 uncovered by the polysilicon layer 28 is removed to obtain a T-shaped profile polysilicon gate.

The polysilicon gate of the present invention not only has a smaller gate line width, but also increases the integration of the device, thereby effectively preventing low polysilicon gate edge breakdown voltage caused by dopant embedded in the edge of the polysilicon gate from the source/drain dopant process.

The embodiment above is only intended to illustrate the present invention; it does not, however, to limit the present invention to the specific embodiment. Accordingly, various modifications and changes may be made without departing from the spirit and scope of the present invention as described in the following claims.

1. A method of fabricating a T-shaped polysilicon gate by using dual damascene process, comprising:
providing a semiconductor substrate having isolation areas formed therein;
forming an oxide layer, a hard mask layer, and a patterned first photoresist layer in sequence on the semiconductor substrate;
performing an etching process on the hard mask layer and the oxide layer by using the patterned first photoresist layer as a mask until the semiconductor substrate is exposed, thereby forming a first trench;
removing the patterned first photoresist layer;
depositing an organic layer in the first trench;
performing an etching back process on the organic layer until the surface of the organic layer is lower than the hard mask layer;
forming a patterned second photoresist layer on the semiconductor substrate to define a second trench dimension to be etched, wherein an etch window dimension of the patterned second photoresist layer is larger than the first trench;
performing an etching process by using the patterned second photoresist layer as a mask to form a second trench;
removing the patterned second photoresist layer and the organic layer;
performing an oxidation process to form a gate oxide layer on the surface of the semiconductor substrate exposed in the first trench;
depositing a polysilicon layer on the semiconductor substrate to fill the first trench and the second trench;
performing a planarization process on the polysilicon layer; and
removing the residual hard mask layer and the exposed oxide layer by using the polysilicon layer as a mask to obtain a T-shaped profile polysilicon gate.

2. The method of fabricating a T-shaped polysilicon gate by using dual damascene process of claim 1, wherein the material of the hard mask layer is selected from silicon oxynitride (SiOH) and tetraethyl-orthosilicate (TEOS).

3. The method of fabricating a T-shaped polysilicon gate by using dual damascene process of claim 1, wherein after obtaining the T-shaped profile polysilicon gate, further performing a source/drain dopant process.

4. The method of fabricating a T-shaped polysilicon gate by using dual damascene process of claim 1, wherein the oxidation process is a Rapid Thermal oxidation process.

5. The method of fabricating a T-shaped polysilicon gate by using dual damascene process of claim 4, wherein the rapid thermal oxidation process is performed by an oxygen plasma.

6. The method of fabricating a T-shaped polysilicon gate by using dual damascene process of claim 1, wherein the planarization process is Chemical Mechanical Polishing (CMP).

7. The method of fabricating a T-shaped polysilicon gate by using dual damascene process of claim 1, wherein the hard mask layer is formed by using Low Pressure Chemical Vapor Deposition.

8. The method of fabricating a T-shaped polysilicon gate by using dual damascene process of claim 1, wherein the organic layer is a Bottom anti-reflective coating (BARC).
